(19) United States
(12) Patent Application Publication
(10) Pub. No.: US 2015/0294697 A1
(43) Pub. Date: Oct. 15, 2015

(54) HIGH SPEED DEGLITCH SENSE AMPLIFIER

(71) Applicant: QUALCOMM Incorporated, San Diego, CA (US)

(72) Inventors: Chulmin Jung, San Diego, CA (US); Rui Li, San Diego, CA (US); David Li, San Diego, CA (US); Tahseen Shakir, San Diego, CA (US); Sei Seung Yoon, San Diego, CA (US)

(73) Assignee: QUALCOMM Incorporated, San Diego, CA (US)

(21) Appl. No.: 14/251,315

(22) Filed: Apr. 11, 2014

(51) Int. Cl. G11C 7/06; G11C 11/419

(52) U.S. Cl. CPC G11C 7/065; G11C 11/419

(57) ABSTRACT

A sense amplifier is provided that includes a skewed latch that latches a voltage difference developed responsive to a read operation on an accessed memory cell. The skewed latch includes a loaded logic gate that is cross-coupled with an unloaded logic gate. The loaded logic gate drives the unloaded logic gate and an output transistor whereas the unloaded logic gate drives only the loaded logic gate.

### TECHNICAL FIELD

This application relates to memories, and more particularly to a glitch-resistant sense amplifier.

### BACKGROUND

During a read cycle in a memory, a word line decoder asserts a selected word line (WL) to a power supply voltage VDD to retrieve the bit values stored in a row of accessed bitcells. In a static random access memory (SRAM), each accessed bitcell drives a corresponding bit line pair comprising a bit line and a complement bit line during the read cycle. A sense amplifier senses the voltages on the bit line and complement bit line to generate a signal that represents the read data for the accessed bitcell. The sense amplifier performs this sensing responsive to a sense enable signal. Due to the time it takes for the voltages on the bit line and the complement bit line to settle to their proper levels after the assertion of the word line voltage, the assertion of the sense amplifier enable signal is delayed with respect to the word line assertion to avoid falsely evaluating glitches as the read data. Thus, an important parameter governing memory performance is the time delay from the assertion of the word line to the assertion of the sense enable (SE) signal. For high-speed memories, minimization of the WL-to-SE delay is critical.

Conventionally, sense amplifiers comprise latch-type sensing devices such as a voltage-latch sense amplifier (VLSA) or a current-latch sense amplifier (CLSA). However, both types of sense amplifiers suffer from drawbacks. For example, a VLSA generally has high capacitive loading on the memory's bit lines and its internal nodes, which leads to excessive slew, and consequently longer WL-to-SE delays and slower read access times. In contrast, a CLSA differentially senses the voltage difference across a bit line pair to provide a data signal that is initially latched before transferring to an output stage. However, the initial latch in the CLSA cannot accommodate false data recovery. Therefore, the corresponding WL-to-SE delay for a CLSA needs to have sufficient margin to minimize the probability that glitches due to the transients on the bit lines are latched when the CLSA is enabled. The probability of false evaluation for a CLSA is thus highly dependent on WL-to-SE timing, necessitating a longer WL-to-SE delay and slower read access time to reduce the failure rate.

Accordingly there is a need in the art for sense amplifiers that are less dependent on extended WL-to-SE delays and are capable of false data recovery.

### SUMMARY

A sense amplifier is provided that makes a bit decision based upon sensing the voltage difference between a bit line and a complementary bit line in a bit line pair. The sense amplifier includes a differential pair of transistors. A first transistor in the pair has its gate driven by the bit line voltage whereas a second transistor in the pair has its gate driven by the complementary bit line voltage. Based upon the voltage difference across the bit line pair, the differential pair of transistors steer a tail current. The steering of the tail current through either the first transistor or the second transistor affects a transistor terminal voltage for each transistor such as a drain terminal voltage. With regard to the differential pair, there is thus a first transistor terminal voltage for the first transistor and a second transistor terminal voltage for the second transistor.

The sense amplifier includes a skewed latch that latches a voltage difference between the first and second transistor terminal voltages for the differential pair of transistors. The skewed latch includes a loaded cross-coupled logic gate that drives an input to an unloaded cross-coupled logic gate. Similarly, the unloaded cross-coupled logic gate drives an input to the loaded cross-coupled logic gate. The unloaded cross-coupled logic gate receives the first transistor terminal voltage whereas the loaded cross-coupled logic gate receives the second transistor terminal voltage. In addition, the loaded cross-coupled logic gate also drives an output transistor whereas the unloaded cross-coupled logic gate does not. The extra capacitive load from the output transistor slows the response time of the loaded cross-coupled logic gate compared to the response time of the unloaded cross-coupled logic gate.

This skewing of the response times in the skewed latch is quite advantageous, For example, suppose the cross-coupled logic gates are both NOR gates and the transistor terminal voltages are defaulted to a power supply voltage VDD when a read operation is not active. Both the NOR gates will thus drive out a zero (ground) in this default state. If the voltages for the bit line and the complementary bit line both remain high due to a glitch during the initial stages of a memory cell access and the differential pair of transistor comprises a pair of NMOS transistors, the transistor terminal voltages (in such an embodiment, the drain voltages for the pair of NMOS transistors) may both initially sag toward ground after a word line voltage and sense enable signal are both asserted. Each NOR gate will then tend to shift its output high. But the loaded NOR gate cannot respond as fast as the unloaded NOR gate such that the unloaded NOR gate then drives a high (VDD) output signal to the unloaded NOR gate while the loaded NOR is still driving a low (ground) output signal to the unloaded NOR gate. The loaded NOR gate will thus keep driving a zero to the output transistor's gate in response to this momentary sag of the transistor terminal voltages. This is the default state for the skewed latch so no error occurs from maintaining this default state in response to this bit line pair voltage glitch. For example, suppose the loaded NOR gate receives the transistor terminal voltage responding to the complement bit line voltage. As this glitch on the bit line pair settles out, it may be the ease that the bit line voltage is maintained high whereas the complement voltage continues to discharge towards ground. The skewed latch will then switch the output transistor on from its default off state.

But if the complement bit line voltage is maintained high while the bit line voltage continues to discharge to ground after resolution of the glitch, the skewed latch will remain in the default state (storing a zero or ground) such that the output transistor is maintained in the default off state. The drain voltage for the output transistor is then maintained high. It will thus be appreciated that regardless of how the glitch on the bit line pair resolves (i.e., regardless of the bit stored in the accessed memory cell), the correct output is provided at the output terminal for the output transistor. This is quite advantageous since the word-line-voltage-to-sense-enable delay may be essentially zero. In one embodiment, the sense enable signal may drive a gate of a current source transistor that generates the tail current steered between the transistors in the differential pair. This sense enable signal may thus be asserted virtually simultaneously with the assertion of the word line voltage, which substantially increases memory speed as compared to prior art solutions. For example, a conventional voltage-latch sense (VLSA) amplifier is slow due to its capacitive loading. Similarly, a conventional current-latch sense amplifier requires a sufficient delay between the assertion of the word line voltage and the sense enable signal assertion to guard against glitches. But the disclosed sense amplifier, which is neither a CLSA nor a VLSA, operates much faster. These and other advantages may be better appreciated through the following detailed description.

### BRIEF DESCRIPTION OF THE DRAWINGS

FIG. 1 is a circuit diagram for an example sense amplifier including a skewed latch in accordance with an embodiment of the disclosure.

FIG. 2 is a timing diagram for a variety of signals for the sense amplifier of FIG. 1 with respect to a read operation on a memory cell storing a first binary value.

FIG. 3 is a timing diagram for a variety of signals for the sense amplifier of FIG. 1 with respect to a read operation on a memory cell storing a second binary value that is the complement of the first binary value.

FIG. 4 is a flowchart for an example method of operation for a sense amplifier in accordance with an embodiment of the disclosure.

### DETAILED DESCRIPTION

A sense amplifier is disclosed that includes a skewed latch that prevents voltage transients on a bit line pair from generating glitches during a read operation. As used herein, a “bit line pair” corresponding to a memory cell refers to the bit line and the complement bit line that couple to the memory cell from the assertion of a corresponding word line voltage during a read operation. The sense amplifier includes a differential pair of transistors having their gates driven by a voltage difference across the bit line pair to steer a tail current. Depending upon the voltage difference, the tail current is steered to flow through either of the transistors in the differential pair. A terminal such as a drain for each transistor in the differential pair forms a corresponding transistor terminal whose voltage changes depending upon whether the tail current is steered through the one transistor or the other in the differential pair responsive to the voltage difference across the bit line pair.

The skewed latch latches the voltage difference between the transistor terminal voltages for the differential pair. To do so, the skewed latch includes a pair of cross-coupled logic gates. Each cross-coupled logic gate in the pair drives an input to the remaining cross-coupled logic gate. A first cross-coupled logic gate in the pair receives as an input one of the differential pair transistor terminal voltages whereas a remaining second one of the cross-coupled logic gates receives as an input a remaining one of the differential pair transistor terminal voltages. With regard to driving each other's inputs and also receiving a corresponding differential pair transistor terminal voltage, the cross-coupled logic gates are balanced with respect to each other. But one of the cross-coupled logic gates also drives a gate of an output transistor having an output terminal representing the bit decision of the sense amplifier. This cross-coupled logic gate is a “loaded” logic gate compared to the remaining one of the cross-coupled logic gates that drives only an input to the loaded cross-coupled logic gate. The remaining cross-coupled logic gate may thus be denoted as an “unloaded” cross-coupled logic gate in that its output does not have the extra capacitive burden of driving the gate of an output transistor. In contrast, the output signal for the loaded cross-coupled logic gate has this extra capacitive burden so that this cross-coupled logic gate is thus slower to change binary states of its output signal as compared to the loaded cross-coupled logic gate.

The following discussion will focus on embodiments in which the differential pair of transistors comprises a pair of NMOS transistors. But it will be appreciated that the concepts disclosed herein are also applicable to embodiments in which the differential pair of transistors comprises a pair of PMOS transistors. For an NMOS pair of differential transistors, the transistor terminal voltages comprise the drains voltages. These terminal voltages are complementary to the bit line voltages. For example, suppose a first one of the transistors in an NMOS differential pair has its gate driven by the bit line voltage. As the bit line voltage rises compared to the complement bit line voltage, the tail current will thus be steered more and more through the first transistor and less and less through a remaining second transistor in the differential pair. The drain voltage for the first transistor (a first transistor terminal voltage) will thus drop towards ground whereas the drain voltage for the second transistor (a second transistor terminal voltage) will remain high. The voltage difference between the first and second terminal voltages for an NMOS differential pair of transistors is thus complementary to the voltage difference between the bit line and complement bit line voltages.

The skewed latch latches the voltage difference between the first and second terminal voltages so that its latched value is also complementary to the voltage difference across the bit line pair. As used herein, the latched value for the skewed latch is deemed to be the output of the loaded cross-coupled logic gate, which drives the gate of the output transistor so that a voltage for an output terminal for the output transistor is responsive to the bit line voltage difference. In a default state in which both terminal voltages are charged high to a power supply voltage VDD, the cross-coupled logic gates within the skewed latch are configured such that both their outputs are low (ground or VSS). For example, the pair of cross-coupled logic gates may comprise a pair of cross-coupled NOR gates. The following discussion will focus on a NOR gate embodiment but it will be appreciated that other types of cross-coupled logic gates may be implemented within the skewed latches disclosed herein.

The loaded cross-coupled NOR gate processes its inputs to form an output signal that drives a gate of the output transistor. For example, in a default state in which the terminal voltages equal VDD, each of the cross-coupled logic gates will output a logical zero (ground or VSS). If a read operation on an accessed memory cell drives the bit line voltage to VDD while the complement bit line is pulsed to ground, the loaded NOR gate will have two zeroes as its input signals such that it will drive the gate of the output transistor with VDD. Conversely, if the read operation on an accessed memory cell pulls the bit line voltage to ground while driving the complement bit line voltage high, the loaded NOR gate will not change from the default state of driving the gate of the output transistor with ground.

The output terminal for an embodiment in which the output transistor is an NMOS transistor may comprise a drain terminal that is connected to a circuit that charges the drain terminal to a power supply voltage VDD in a default state. If the memory cell being accessed drives the bit line voltage high and the complement bit line voltage low, the drain terminal for the output transistor will thus be discharged because the loaded NOR gate will output a high value (VDD) that turns on the NMOS output transistor so as to pull its drain terminal to ground. In one embodiment, an accessed memory cell that drives the bit line voltage high while discharging the complement bit voltage may be deemed to store a logical one. Conversely, an accessed memory cell that discharges the bit line voltage while maintaining the complement bit line voltage high may be deemed to store a logical zero. In such a ease, the output drain terminal for the output transistor will remain charged in response to the memory cell access.

In a cross-coupled NOR gate embodiment, there are thus at least two possibilities for glitches. In particular, note that the default state for the first and second transistor terminal voltages for the differential pair of transistors is VDD. The first terminal voltage drives the unloaded NOR gate whereas the second terminal voltage drives the loaded NOR gate. A first glitch may thus comprise the first terminal voltage initially sagging during a memory cell access but then correcting back to its intended value of VDD. A second glitch may comprise the second terminal voltage initially sagging but then correcting back to its intended value of VDD. One can immediately appreciate that the loaded cross-coupled NOR gate makes the sense amplifier robust to the both the first and second glitches because the loaded NOR gate is slower to respond than the unloaded NOR gate. For example, with regard to the first glitch, the unloaded NOR gate's output signal may temporarily be driven high. But such a temporary state has no effect on the loaded NOR gate's output, which was already low in its default state. With regard to the second glitch, note that the accessed memory cell may be storing a logical one such that the bit line voltage will eventually resolve high, bringing the first terminal voltage low. The unloaded NOR gate will respond more quickly than the loaded NOR gate, which maintains its default state of driving a low output for the time being while the unloaded NOR gate drives it output high. The high output from the unloaded NOR gate protects the slower loaded NOR gate from ever responding to the temporary sagging of the second terminal voltage. The skewing of the cross-coupled NOR gates is thus quite advantageous with regard to resisting glitches and recovering from any glitch that would undesirably turn on the output transistor. These advantages may be better appreciated with regard to the following example embodiment.

### Example Embodiment

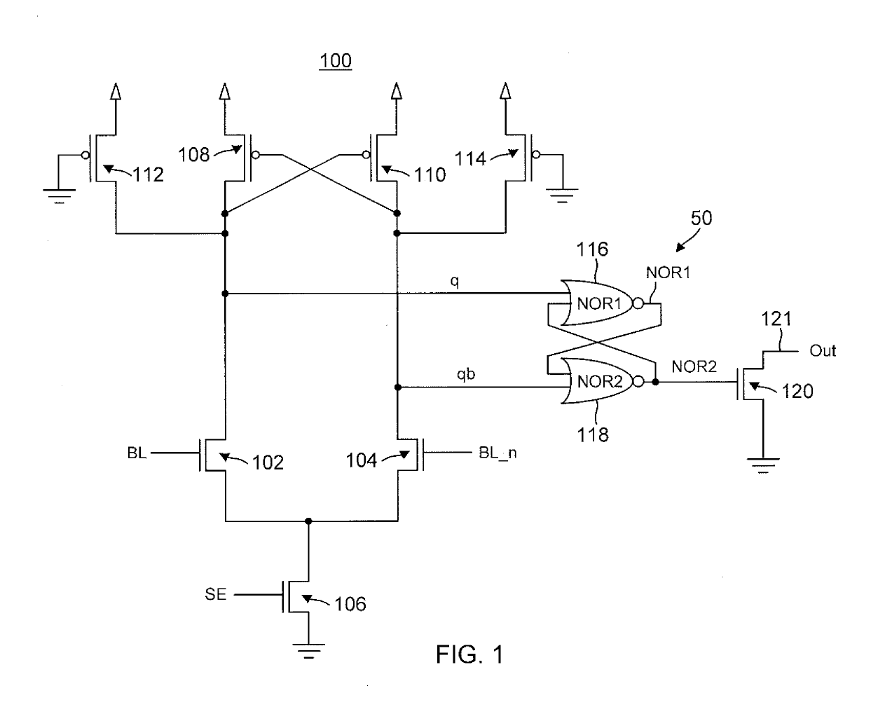

FIG. 1 illustrates a sense amplifier 100 with a skewed latch 50. The following discussion focuses on the innovative deglitching properties for sense amplifier 100. Thus the memory cells are not shown. In that regard, it will be appreciated that a memory such as an SRAM includes a plurality of SRAM bitcells (which may also be denoted as memory cells) for each bit line pair. A plurality of word lines correspond to rows of the memory cells whereas the bit line pairs correspond to columns of the memory cells. Each memory cell belongs to both a row and a column and thus corresponds to a bit line pair/word line intersection. The number of rows depends upon a memory's depth whereas the number of columns (bit line pairs) depends upon a memory's word width. Because such features are all well known in the SRAM arts, the bitcells and their word lines are not illustrated for sense amplifier 100.

The bit line BL and a complement bit line BL_n from a bit line pair that drive the gates, respectively, of a differential pair of NMOS transistors 102 and 104. An NMOS current source or biasing transistor 106 that couples between ground and the sources for the differential pair of transistors 102 and 104 has its gate driven by a sense enable signal (SE). Thus, when the sense enable signal is asserted to trigger a sense operation by sense amplifier 100, a tail current conducted by current source transistor 106 will steer between the differential pair transistors 102 and 104 depending upon the binary value stored in the accessed memory cell (not illustrated). For example, suppose the memory cell stores a binary value such that the bit line voltage BL is maintained at VDD whereas the complement bit line voltage BL_n discharges towards ground. The tail current generated by current source transistor 106 should then be directed largely through differential pair transistor 102 and much less through differential pair transistor 104. The drain voltage for differential pair transistor 102 will thus drop towards ground (VSS) whereas the drain voltage for differential pair transistor 104 will remain high at a supply voltage (VDD). The terminal voltages discussed above are defined with regard to the drain voltages for transistors 102 and 104. A first terminal voltage is the drain voltage for differential pair transistor 102 (designated as q). Similarly, a second terminal voltage is the drain voltage for differential pair transistor 104 (designated as qb).

A complementary binary state stored in the accessed memory cell would thus produce a complementary voltage state for first and second transistor terminal voltages q and qb such that second transistor terminal voltage qb would be pulled towards ground whereas first transistor terminal voltage q would remain at VDD. A pair of weak pull-up or keeper PMOS transistors 112 and 114 are configured to keep the first and second transistor terminal voltages q and qb at VDD during a default state (no memory cell access). The gates of pull-up transistors 112 and 114 are grounded so they both are maintained on. Pull-up transistor 112 couples between a power supply node supplying the power supply voltage VDD and the drain of differential pair transistor 102 and thus functions to weakly pull the first terminal voltage q to VDD. Similarly, pull-up transistor 114 couples between the power supply node and the drain for differential pair transistor 104 and thus functions to weakly pull the second terminal voltage qb to VDD.

A pair of cross-coupled feedback PMOS transistors 108 and 110 are configured to assist the differential voltage development difference between the first and second terminal voltages q and qb. Feedback PMOS transistor 108 couples between the power supply node and the drain of differential pair transistor 102. Similarly, feedback PMOS transistor 110 couples between the power supply node and the drain of differential pair transistor 104. The second terminal voltage qb drives the gate of feedback PMOS transistor 108 whereas the first terminal voltage q drives the gate of feedback PMOS transistor 110. Thus, if the bit line pair voltage is such that the tail current is steered through differential pair transistor 102, the falling voltage for the first terminal voltage q will switch feedback transistor 110 on to assist in maintaining the second terminal voltage qb at VDD. But this boost of the second terminal voltage qb to VDD keeps feedback transistor 108 off so that the first terminal voltage q stays low. Conversely, a complementary binary state in the accessed memory cell would cause the tail current to steer through differential pair transistor 104 such that the falling voltage for second terminal voltage qb would cause feedback transistor 108 to turn on, which in turn maintains the first terminal voltage q at VDD. Conversely, the charging of the first terminal voltage q to VDD maintains feedback transistor 110 off so that the second terminal voltage qb is maintained low.

To summarize, the default state for the first and second terminal voltages is thus VDD as maintained by weak pull-up transistors 112 and 114. The voltage difference impressed on the bit line pair from a memory cell access is then amplified by the cross-coupled feedback transistors 108 and 110 such that the first and second terminal voltages will quickly develop into complementary states (one being VDD while the other is ground (VSS)) during a memory cell access depending upon the binary value stored in the accessed memory cell.

To respond to the first and second terminal voltages q and qb, skewed latch 50 comprises a pair of cross-coupled logic gates such as NOR gates 116 and 118. NOR gate 118 drives a gate of an NMOS output transistor 120 with a second output signal NOR2, which also drives an input for NOR gate 116. In contrast, NOR gate 116 drives only the input of NOR gate 118 with a first output signal NOR1. NOR gate 118 is thus a loaded NOR gate whereas NOR gate 116 is an unloaded NOR gate. Unloaded NOR gate 116 processes the first terminal voltage q and second output signal NOR2 to form first output signal NOR1. Similarly, loaded NOR gate 118 processes the second terminal voltage qb and first output signal NOR1 to form second output signal NOR2.

Due to its lack of loading, unloaded NOR gate 116 responds more quickly to changes on first terminal voltage q as compared to the speed with which loaded NOR gate 118 responds to changes on the second terminal voltage qb. This speed difference is why latch 50 is designated herein as a “skewed latch.” NMOS output transistor 120 has its source coupled to ground and a drain coupled to an output node or terminal 121. A circuit such a weak pull-up transistor (not illustrated) charges output terminal 121 high to VDD in the default state. Since the first and second terminal voltages q and qb also equal VDD in the default state, the output signals NOR1 and NOR 2 for NOR gates 116 and 118 will both be low in the default state. Output transistor 120 is thus off in the default state such that a voltage for output terminal 121 will remain high in the default state.

In one embodiment, output transistor 120 may be deemed to comprise a means for producing an output signal at output terminal 121 responsive to the latching of a voltage difference in a skewed latch, wherein the output signal represents a result of a read operation on an accessed memory cell.

The skewing of skewed latch 50 is quite advantageous. For example, suppose that due to a momentary voltage glitch, both first transistor terminal voltage q and the second transistor terminal voltage qb momentarily drop in response to the assertion of the word line voltage during a memory cell access to a memory cell coupled through a word line voltage assertion to the bit line pair including bit line BL and complement bit line BL_n. This is undesirable as a voltage difference should ordinarily develop across the bit line pair in response to whatever binary value is stored in the accessed memory cell. But this momentary voltage glitch does not produce such a voltage difference but instead initially maintains the voltage for the bit line BL and for the complement bit line BL_n high such that both first and second transistor terminal voltages q and qb initially sag at the beginning of a memory cell access in response to the word line assertion. But no glitch is produced at output terminal 121 because loaded NOR gate 116 responds quickly to the dropping of the first transistor terminal voltage q. In particular, note that the output signal NOR2 from loaded NOR gate 118 is low in the default state such that unloaded NOR gate 116 then responds to its two low inputs by driving its output signal NOR1 high. Loaded NOR gate 118 cannot respond so quickly to the low value the glitch has induced in second transistor terminal voltage qb. Moreover, the high value for output signal NOR1 from unloaded NOR gate 116 then forces loaded NOR gate 118 to keep its output signal NOR2 low.

As the glitch resolves itself, the bit line pair voltages will develop responsive to the binary value of the accessed memory cell. For example, suppose that the binary value of the accessed memory cell is such that the first transistor terminal voltage q recovers high after the glitch and the second transistor terminal voltage qb drops to ground. Loaded NOR gate 118 will then charge its output signal NOR2 to VDD to turn on output transistor 120 and pull output terminal 121 low, which is the proper response. Conversely, if the binary value of the accessed memory cell is such that the second transistor terminal voltage qb recovers high after the glitch and the first transistor terminal voltage q drops to ground, loaded NOR gate 118 will continue to maintain its output signal NOR2 low so that output transistor 120 stays off and output terminal 121 stays high, which is again the proper response. The glitch thus resolves to the proper voltage state for output terminal 121 regardless of the binary value stored in the accessed memory cell.

Another voltage glitch may have the second transistor terminal voltage qb momentarily drop low while first terminal voltage q stays high. Furthermore, suppose the binary state of the accessed memory cell is such that as this glitch resolves itself, the first transistor terminal voltage q will drop to ground and the second transistor terminal voltage qb will resolve itself high to VDD. In a worst case process corner, this momentary glitch may be prolonged enough that loaded NOR gate 118 will begin to switch on output transistor 120 momentarily. But as the glitch resolves itself, the weak pull-up from pull-up transistor 114 helps charge the second transistor terminal voltage qb back to VDD. Thus, the loaded NOR gate 118 will recover and pull its output low to switch output transistor 120 off. In this fashion, deglitch sense amplifier 100 is not only resistant to glitches but also recovers quickly from any glitch that overcomes its resistance. The word-line-to-sense-enable delay may thus be reduced as compared to conventional memory operation, which increases memory speed. Moreover, sense amplifier 100 is faster than a conventional voltage-latching sense amplifier because there is less capacitive loading with regard to the first and second transistor terminal voltages q and qb. Similarly, sense amplifier 100 is faster than a conventional current-latching sense amplifier because of the elimination of the initial latching stage. In that regard, a conventional current-latching sense amplifier not only is slower but also cannot recover from temporary glitches.

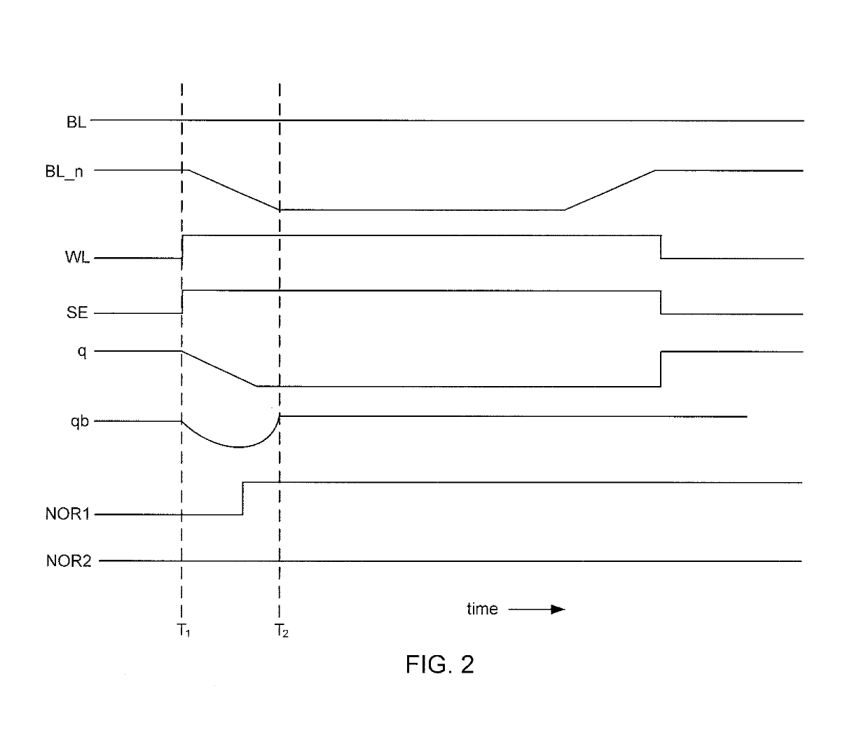

To better illustrate the advantageous properties of sense amplifier 100, some example timing diagrams will now be discussed. FIG. 2 illustrates the timing of various signals for sense amplifier 100 of FIG. 1 when the binary value for the accessed memory cell (not illustrated) is such that the bit line BL voltage is driven high and the complement bit line BL_n voltage discharges to ground. Prior to a read cycle beginning at time T₁, the sense enable SE signal is maintained at logic low to disable operation of sense amplifier 100. The voltages for the bit line BL and complement bit line BL_n are in their default state of VDD prior to time T₁. Similarly, the first transistor terminal voltage q and the second transistor terminal voltage qb signals are also in their default value of VDD prior to time T₁. In turn, the output signals NOR1 and NOR2 are also in their default state of logic low (ground) prior to time T₁. The start of the read cycle is indicated by the assertion of a word line voltage WL to couple the accessed memory cell or bitcell to the bit lines at time T₁. The sense enable signal SE may also be asserted at this time such that there is effectively no word-line-to-sense-enable delay. This delay may be non-zero in alternative embodiments. The accessed memory cell will then begin to discharge the voltage for the complement bit line BL_n while the voltage for the bit line BL remains at VDD. But the discharge of the complement bit line BL_n voltage takes some delay such that the complement bit line BL_n voltage is not completely discharged until a time T₂. Given the assertion of the sense enable SE at time T₁, not only the first transistor terminal voltage q but also the second transistor terminal voltage qb may begin to discharge immediately after time But the unloaded NOR gate (not illustrated) producing the NOR1 output signal responds more quickly than the loaded NOR gate (not illustrated) producing the NOR2 output signal. The NOR2 output signal is thus maintained in its default state as the second transistor terminal voltage qb sags.

In contrast, the NOR1 output signal is driven high from its default state in response to the drop in the first transistor terminal voltage q. This high state for the NOR1 output signal then prevents the loaded NOR gate from responding to the sag in the second transistor terminal voltage qb. Instead, the second transistor terminal voltage qb can be pulled back up to VDD by time T₂ from the drop in the complement bit line BL_n voltage. The NOR2 output signal thus never responds to the glitch on the second transistor terminal voltage q2 but instead is maintained in its default low state, which is what is desired for this particular binary state in the accessed memory cell.

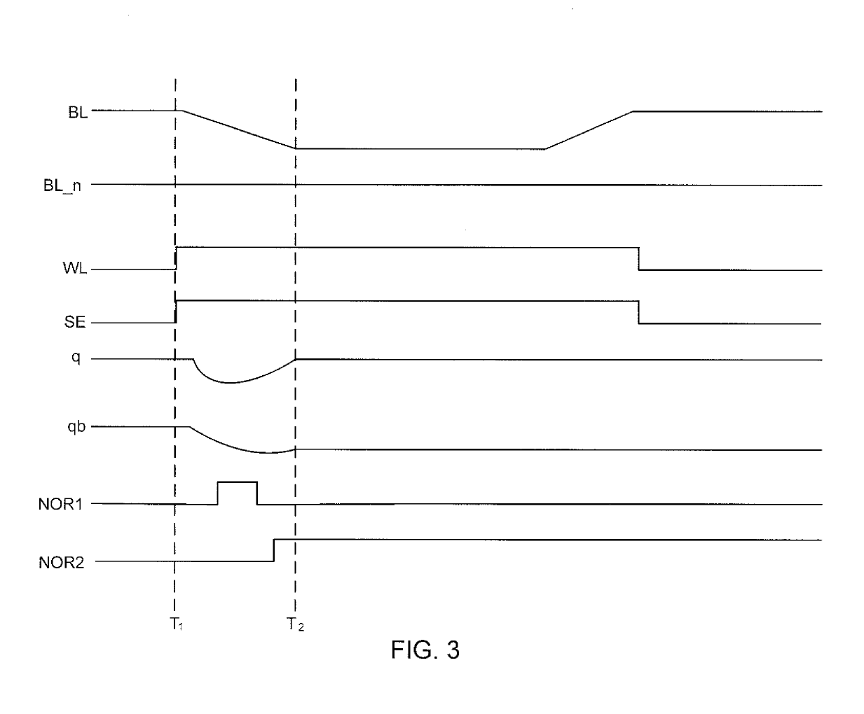

FIG. 3 shows the complementary scenario to FIG. 2. The accessed memory cell (not illustrated) for FIG. 3 thus drives the bit line BL voltage low while maintaining the complement bit line BL_n voltage at VDD after the assertion of the word line WL voltage at time T₁. It takes some delay for the bit line BL voltage to discharge such that the bit line BL voltage is not fully discharged until time T₂. The sense enable signal SE is also asserted at time T₁ such that the initial high state for the bit line BL voltage right after time T₁ causes the first transistor terminal voltage q to sag between time T₁ and time T₂. The fast response of the unloaded NOR gate (not illustrated) producing the NOR1 output signal may thus glitch between time T₁ and T₂ to produce a momentary VDD voltage pulse. But this momentary high state on the NOR1 output signal is harmless since the NOR2 output signal from the loaded NOR gate (not illustrated) was in its low default state prior to time T₁ and is thus maintained in this default state while the NOR1 output signal glitches. But the fast response for the unloaded NOR gate allows the NOR1 output signal to quickly resolve itself back to ground as the bit line BL voltage continues to drop. The slower loaded NOR gate can then respond to the drop in the NOR1 output signal and the drop in the second transistor terminal voltage qb so as to drive the NOR2 output signal high as desired. The NOR2 output signal thus never responds to the glitch on the first transistor terminal voltage q. An example method of operation will now be discussed.

### Example Method of Operation

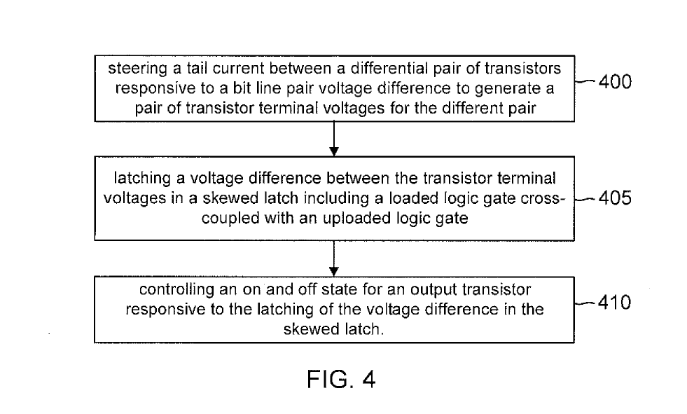

FIG. 4 is a flowchart for an example method of operation for a sense amplifier as disclosed herein. A step 400 comprises steering a tail current between a differential pair of transistors responsive to a hit line pair voltage difference to generate a pair of transistor terminal voltages for the differential pair. Transistors 102 and 104 represent an example of such a differential pair of transistors generating first transistor terminal voltage q and second transistor terminal voltage qb. A step 405 comprises latching a voltage difference between the transistor terminal voltages in a skewed latch including a loaded logic gate cross-coupled with an unloaded logic gate. Skewed latch 150 is an example of such a latching of a voltage difference. Finally, a step 410 comprises controlling an on and off state for an output transistor responsive to the latching of the voltage difference in the skewed latch. The NOR2 output signal controlling output transistor 120 is an example of such a controlling step.

As those of some skill in this art will by now appreciate and depending on the particular application at hand, many modifications, substitutions and variations can be made in and to the materials, apparatus, configurations and methods of use of the devices of the present disclosure without departing from the spirit and scope thereof In light of this, the scope of the present disclosure should not be limited to that of the particular embodiments illustrated and described herein, as they are merely by way of some examples thereof, but rather, should be fully commensurate with that of the claims appended hereafter and their functional equivalents.

What is claimed is:

1. A sense amplifier, comprising:
a differential pair of transistors configured to differentially drive a first transistor terminal voltage for a first one of the transistors in the differential pair and a second transistor terminal voltage for a remaining second one of the transistors in the differential pair responsive to a bit line voltage difference across a bit line pair;
an output transistor; and
a skewed latch comprising a pair of cross-coupled logic gates, wherein a first one of the cross-coupled logic gates is configured to process the first transistor terminal voltage and an output from a remaining second one of the cross-coupled logic gates into a first output signal, and wherein the second cross-coupled logic gate is configured to process the first output signal and the second transistor terminal voltage into a second output signal for driving a gate of the output transistor.

2. The sense amplifier of claim 2, further comprising a pair of keeper transistors configured to weakly charge the first terminal voltage and the second terminal voltage to a supply voltage VDD.

3. The sense amplifier of claim 2, further comprising a current source transistor configured to generate a tail current responsive to an assertion of a sense enable signal, and wherein the differential pair of transistors is coupled in parallel to a drain for the current source transistor.

4. The sense amplifier of claim 1, wherein the pair of cross-coupled logic gates comprises a pair of cross-coupled NOR gates.

5. The sense amplifier of claim 1, further comprising a pair of cross-coupled feedback transistors, wherein a first one of the cross-coupled transistors is configured to drive the first transistor terminal voltage to VDD responsive to a discharge of the second transistor terminal voltage, and wherein a second one of the cross-coupled transistors is configured to drive the second transistor terminal voltage to VDD responsive to a discharge of the first transistor terminal voltage.

6. The sense amplifier of claim 5, wherein the pair of cross-coupled feedback transistors comprises a first PMOS transistor coupled between a power supply node and a drain for the first transistor in the differential pair and a second PMOS transistor coupled between the power supply node and a drain for the second transistor in the differential pair.

7. The sense amplifier of claim 1, wherein the differential pair of transistors comprises a pair of NMOS transistors.

8. The sense amplifier of claim 1, wherein the output transistor comprises an NMOS transistor having a source coupled to ground and having a drain terminal as an output terminal, the sense amplifier further comprising a weak pull-up transistor configured to weakly pull the drain for the output transistor to a power supply voltage VDD.

9. A method, comprising:
steering a tail current between a differential pair of transistors responsive to a bit line pair voltage difference to generate a pair of transistor terminal voltages for the differential pair;
latching a terminal voltage difference between the transistor terminal voltages in a skewed latch including a loaded logic gate cross-coupled with an unloaded logic gate; and
controlling an on and off state for an output transistor responsive to the latching of the terminal voltage difference in the skewed latch.

10. The method of claim 9, further comprising generating the tail current in a current source transistor responsive to an assertion of a sense enable signal.

11. The method of claim 9, wherein generating the tail current is further responsive to an assertion of a word line voltage.

12. The method of claim 9, further comprising weakly pulling the transistor terminal voltages to a power supply voltage VDD.

13. The method of claim 9, wherein latching the terminal voltage difference in the skewed latch comprises driving the unloaded cross-coupled logic gate with a first one of the transistor terminal voltages and driving the loaded cross-coupled logic gate with a second one of the transistor terminal voltages.

14. The method of claim 9, further comprising generating the bit line voltage difference responsive to an assertion of a word line voltage.

15. A sense amplifier, comprising:
a skewed latch configured to latch a voltage difference responsive to a coupling of a memory cell to a bit line and a complement bit line; and
means for producing an output signal responsive to the latching of the voltage difference in the skewed latch, wherein the output signal represents a result of a read operation on an accessed memory cell.

16. The sense amplifier of claim 15, further comprising a differential pair of transistors, wherein a first one of the transistors in the differential pair has its gate coupled to the bit line and a remaining second one of the transistors in the differential pair has its gate coupled to the complement bit line.

17. The sense amplifier of claim 15, wherein the means comprises an output transistor.

18. The sense amplifier of claim 16, wherein the differential pair of transistors comprises a pair of NMOS transistors.

19. The sense amplifier of claim 16, further comprising a pair of weak pull-up transistors, wherein a first one of the weak pull-up transistors is coupled between a power supply node and a drain for the first transistor in the differential pair, and wherein a second one of the weak pull-up transistors is coupled between the power supply node and a drain for the second transistor in the differential pair.

20. The sense amplifier of claim 19, wherein the pair of weak pull-up transistors comprises a pair of PMOS transistor having grounded gates.
